(19) United States
(12) Patent Application Publication
(10) Pub. No.: US 2009/0290417 A1
(43) Pub. Date: Nov. 26, 2009

(54) NONVOLATILE MEMORY DEVICE AND METHOD OF FABRICATING THE SAME

(75) Inventors: Myoung-Kyu PARK, Gyeonggi-do (KR); Byung-Sun KIM, Gyeonggi-do (KR); Tae-Jung LEE, Gyeonggi-do (KR); Dong-Ryul CHANG, Gyeonggi-do (KR)

Correspondence Address: MUIR PATENT CONSULTING, PLLC, 758 WALKER RD, SUITE C, GREAT FALLS, VA, 22066, US

(73) Assignee: Samsung Electronics Co., Ltd., Gyeonggi-do (KR)

(21) Appl. No.: 12/348,185

(22) Filed: Jan. 2, 2009

(30) Foreign Application Priority Data
May 20, 2008 (KR) 2008-0046620

(51) Int. Cl. G11C 16/04; H01L 29/788

(52) U.S. Cl. 365/185.08; 365/185.05; 257/315; 257/E29.3

(57) ABSTRACT

A nonvolatile memory device including a plurality of word lines; a plurality of bit lines intersecting the word lines; a plurality of memory cells corresponding to intersections of the word lines and the bit lines; a common control gate line commonly connected to the memory cells; and a common erasing gate line commonly connected to the memory cells.

### CROSS-REFERENCE TO RELATED PATENT APPLICATIONS

This application claims the benefit of Korean Patent Application No. 10-2008-0046620, filed on May 20, 2008, in the Korean Intellectual Property Office, the disclosure of which is incorporated herein in its entirety by reference.

### BACKGROUND

1. Technical Field

This disclosure relates to a nonvolatile memory device and a method of fabricating the same, and more particularly, to a nonvolatile memory with a single gate structure and a method of fabricating the same.

2. Description of the Related Art

Semiconductor memory devices for storing data can be largely divided into volatile memory devices and nonvolatile memory devices. In a volatile memory device, data stored is lost when power supply is discontinued, whereas in a nonvolatile memory device, data stored is retained even when power supply is discontinued. Electrically erasable programmable read only memory (EEPROM) is a type of nonvolatile memory device in which data can be electrically stored and erased.

Such EEPROM can be extensively used in display driver integrated chips (DDIs), such as a liquid crystal display driver IC (LDI). In general, a high voltage, e.g., 18 V, is necessary to operate the EEPROM. Conventionally, an additional high-voltage process is not required to manufacture EEPROM since a high-voltage process is used in manufacturing a DDI. Recently, low-temperature poly silicon (LTPS) substrates have been used as substrates in which a DDI is mounted. However, in the case of LTPS, a high-voltage process is not necessary to manufacture a DDI since the LTPS can be manufactured as a high-voltage device.

### SUMMARY

An embodiment includes a nonvolatile memory device including word lines; bit lines intersecting the word lines; memory cells corresponding to intersections of the word lines and the bit lines; a common control gate line commonly connected to the memory cells; and a common erasing gate line commonly connected to the memory cells.

Another embodiment includes a nonvolatile memory device including a substrate of a first conductive type; a first well of the first conductive type formed on the substrate; a second well of a second conductive type formed on the substrate to be spaced apart from the first well, and having a first impurities region connected to a common control gate line; a third well of the second conductive type formed on the substrate to be spaced apart from the first and second wells, and having a second impurities region connected to a common erasing gate line; and a floating gate formed on the first through third wells, and capacitively-coupled to a region of the first well, the first impurities region, and the second impurities region.

Another embodiment includes a method of fabricating a nonvolatile memory device including forming first, second and third wells on a substrate spaced apart from one another; forming a first impurities region in the second well coupled to a common control gate line; forming a second impurities region in the third well coupled to a common erasing gate line; and forming a floating gate on the first, second and third wells capacitively-coupled to a region of the first well, the first impurities region and the second impurities region.

### BRIEF DESCRIPTION OF THE DRAWINGS

The above and other features and advantages of embodiments will be described with reference to the attached drawings in which:

FIG. 1 is a circuit diagram of a unit cell of a nonvolatile memory according to an embodiment;

FIG. 2 illustrates the layout of the unit cell of the nonvolatile memory of FIG. 1 according to an embodiment;

FIG. 3 is a cross-sectional view taken along the line I-I′ of FIG. 2;

FIG. 4 is a circuit diagram of a nonvolatile memory cell array according to an embodiment;

FIG. 5 is a circuit diagram of a booting circuit included in a nonvolatile memory device according to an embodiment;

FIG. 6 is a graph illustrating a voltage at a point where two transistors included in a unit cell of a nonvolatile memory intersect each other versus the ratio of the channel widths of the two channels, according to an embodiment;

FIG. 7 is a graph illustrating a variation in a threshold voltage when programming a unit cell of a nonvolatile memory versus the ratio of the channel widths of two transistors included in the unit cell, according to an embodiment;

FIG. 8 is a flowchart illustrating a method of fabricating a nonvolatile memory device according to an embodiment;

FIG. 9 is a block diagram schematically illustrating a card according to an embodiment; and

FIG. 10 is a block diagram schematically illustrating a system according to an embodiment.

### DETAILED DESCRIPTION OF THE EMBODIMENTS

Embodiments will be described in reference to the accompanying drawings. However, embodiments are not limited to the particular embodiments illustrated or described hereinafter. The embodiments herein are rather introduced to provide easy and complete understanding of the scope and spirit of embodiments. Moreover, in the drawings, the thicknesses of layers and regions are exaggerated for clarity.

It will be understood that when an element, such as a layer, a region, or a substrate, is referred to as “on,” “connected to” or “coupled to” another element, it can be directly on, connected or coupled to the other element or intervening elements can be present. In contrast, when an element is referred to as “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. can be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “above,” “upper,” “beneath,” “below,” “lower,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” can encompass both an orientation of above and below. The device can be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but can be to include deviations in shapes that result, for example, from manufacturing. For example, an implanted region illustrated as a rectangle can, typically, have rounded or curved features and/or a gradient of implant concentration at its edges rather than a discrete change from implanted to non-implanted region. Likewise, a buried region formed by implantation can result in some implantation in the region between the buried region and the surface through which the implantation takes place. Thus, the regions illustrated in the figures are schematic in nature and their shapes can be not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

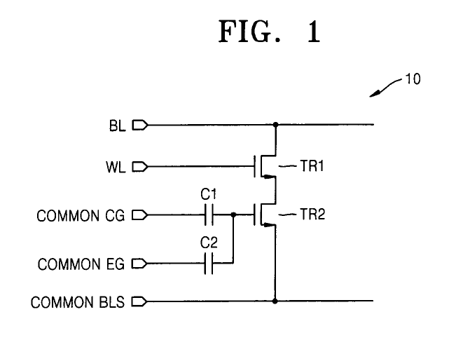

FIG. 1 is a circuit diagram of a unit cell 10 of nonvolatile memory according to an embodiment. Referring to FIG. 1, the unit cell 10 includes a first transistor TR1 and a second transistor TR2 that are connected in series. Hereinafter, for convenience of explanation, EEPROM will be described as an example of nonvolatile memory. However, it would be apparent to those of ordinary skill in the art that the present invention is not limited to the EEPROM.

The first transistor TR1 includes a source connected to a bit line BL and a gate connected to word line WL. Whether to program, read data from, or erase data from the unit cell 10 is selected based on voltage applied to the bit line BL and the word line WL connected to the first transistor TR1. Thus, the first transistor TR1 is also referred to as a selection transistor.

The second transistor TR2 includes a floating gate capacitively-coupled to a control gate and an erasing gate, and a drain connected to a common bit line selection (BLS) line. The common BLS line is commonly connected to multiple memory cells. Here, the second transistor TR2 performs programming or a read operation on the unit cell 10 and thus is also referred to as an access transistor.

More specifically, the floating gate can form one electrode of a control metal oxide semiconductor (MOS) capacitor C12, and the other electrode of the control MOS capacitor C1 can be referred to as a control gate. The other electrode of the control MOS capacitor C1 is connected to a common control gate (CG) line. The common control gate line is commonly connected to multiple memory cells. Also, the floating gate can form one electrode of an erasing MOS capacitor C2 and the other electrode of the erasing MOS capacitor C2 can be referred to as an erasing gate. The other electrode of the erasing MOS capacitor C2 is connected to a common erasing gate (EG) line. The erasing EG line is commonly connected to multiple memory cells.

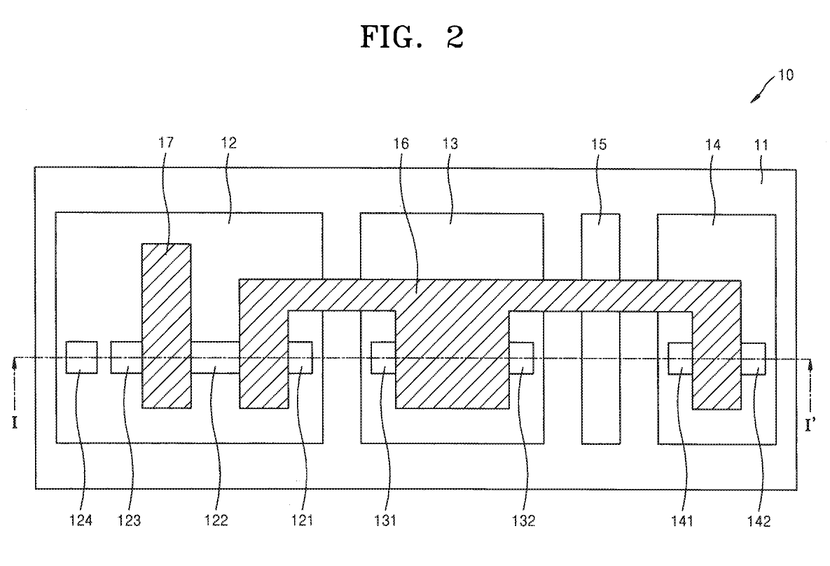

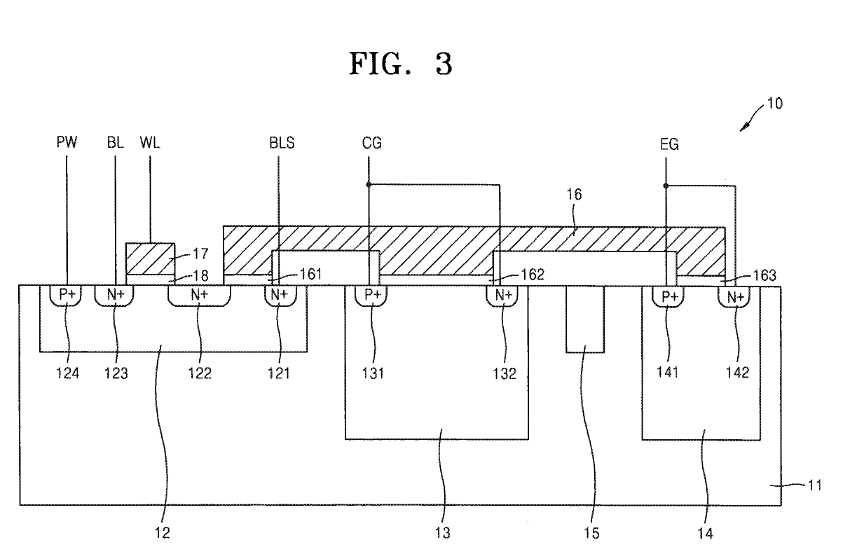

FIG. 2 illustrates the layout of the unit cell 10 of the nonvolatile memory of FIG. 1 according to an embodiment. FIG. 3 is a cross-sectional view taken along the line I-I′ of FIG. 2. Referring to FIGS. 2 and 3, the unit cell 10 includes a substrate 11, and first through fourth wells 12 through 15 formed in the substrate 11. In an embodiment, the substrate 11 can be a P type semiconductor substrate, the first and fourth wells 12 and 15 can be P type wells, and the second and third wells 13 and 14 can be N type wells. However, it would be apparent to those of ordinary skill in the art that the conductive types of the substrate 11 and the first through fourth wells 12 through 15 are not limited thereto.

The substrate 11 can be a semiconductor substrate. For example, the substrate 11 can be formed of one of silicon, silicon-on-insulator, silicon-on-sapphire, germanium, silicon-germanium, gallium-arsenide, or the like.

The first well 12 is a low-voltage P type well formed on the substrate 11. In the first well 12, first through third source/drain regions 121, 122, and 123, and a first well tab 124 are formed. In an embodiment, the first well 12 can be formed on the substrate 11 through ion implantation. The first through third source/drain regions 121, 122, and 123 can be N+ type impurities regions while spaced apart from one another, thereby constructing an NMOS transistor.

A first dielectric layer 18 is formed on the first well 12 between the second and third source/drain regions 122 and 123, and a gate 17 is formed on the first dielectric layer 18. Thus, the second and third source/drain regions 122 and 123, the first dielectric layer 18 and the gate 17 form the selection transistor. The gate 17 is connected to a word line WL corresponding to the unit cell 10, and the second source/drain region 123 is connected to a bit line BL corresponding to the unit cell 10.

A second dielectric layer 161 is formed on the first well 12 between the first and second source/drain regions 121 and 122, and a floating gate 16 is formed on the second dielectric layer 161. Thus, the first and second source/drain regions 121 and 122, the second dielectric layer 161, and the floating gate 16 form an access transistor. The first source/drain region 121 is connected to a common bit line selection (BLS) line.

In an embodiment, the first dielectric layer 18 and the second dielectric layer 161 can be silicon oxide layers or other high k-dielectric dielectric layers. For example, the high k-dielectric dielectric layer can include one of a silicon nitride oxide layer, an aluminum oxide layer, a lanthanum oxide layer, a lanthanum aluminum oxide layer, a hafnium oxide layer, a hafnium aluminum oxide layer, a lanthanum hafnium oxide layer, a zirconium oxide layer, a tantalum oxide layer, or the like or can include a multi-level layer structure made of a combination thereof. The high k-dielectric layer is just illustrative and thus, embodiments are not limited to the above examples of layers. These layers can be formed through chemical vapor deposition, atomic layer deposition, or the like as known in the technical field and/or appropriate to the particular layer or layers.

In an embodiment, the first through third source/drain regions 121 through 123 can be N+ type impurities regions, and the selection transistor and the access transistor can be NMOS transistors. However, the present invention is not limited thereto, and the selection transistor and the access transistor can be PMOS transistors obtained by forming P+ type impurities regions in an N type well.

Also, the first well tab 124 is a P+ type impurities region whose conductive type is the same as the first well 12 while spaced apart from the first through third source/drain regions 121 through 123. The concentration of impurities in the first well tab 124 is higher than in the first well 12. A voltage is applied to the substrate 11 via the first well tab 124.

The second well 13 is a low-voltage N type well formed on the substrate 1 spaced apart from the first well 12, and includes a first impurities region 131 and a second well tab 132 to which common programming voltage is applied. Here, the second well 13 can be formed on the substrate 11 through ion implantation. The second well 13 functions as a control gate when common programming voltage is applied to the first impurities region 131 and the second well tab 132 while connected to a common control gate line. A third dielectric layer 162 is formed on the second well 13 between the first impurities region 131 and the second well tab 132, and the floating gate 16 is connected to an upper part of the third dielectric layer 162. Accordingly, the floating gate 16 and a control gate are capacitively-coupled via the third dielectric layer 162.

The second well 13 is spaced apart from the first well 12 in order to prevent avalanche breakdown from occurring at a junction between the first well 12 and the second well 13. For example, the second well 13 can be spaced apart from the first well 12 by about 0.5 to 2 μm.

Here, the first impurities region 131 can be formed of P+ type impurities, the conductive type of which is different from that of the second well 13 so that it can function as a drain in the second well 13. Also, the second well tab 132 is formed of N+ type impurities region, the conductive type of which is the same as that of the second well 13 while spaced apart from the first impurities region 131. The concentration of impurities in the second well tab 132 is higher than in the second well 13. The third well 14 is a low-voltage N type well formed on the substrate 11 spaced apart from the second well 13, and includes a second impurities region 141 and a third well tab 142 to which common erasing voltage is applied. Here, the third well 14 can be formed on substrate 11 through ion implantation. The third well 14 functions as an erasing gate when common erasing voltage is applied to the second impurities region 141 and the third well tab 142 while connected to a common erasing gate line. A fourth dielectric layer 163 is formed on the third well 14 between the second impurities region 141 and the third well tab 142, and the floating gate 16 is connected to an upper part of the fourth dielectric layer 163. Accordingly, the floating gate 16 and the erasing gate are capacitively-coupled via the fourth dielectric layer 163.

In an embodiment, the second well 13 and the third well 14 are formed on the substrate 11 spaced a predetermined distance from each other, thereby electrically disconnecting the second and third wells 13 and 14 from each other. For example, the third well 14 can be spaced apart from the second well 13 by about 2 to 4 μm.

The second impurities region 141 can be formed of P+ type impurities, the conductive type of which is different from that of the third well 14 so that it can function as a drain on the third well 14. Also, the third well tab 142 is an N+ type impurities region, the conductive type of which is the same as that of the third well 14 while spaced apart from the second impurities region 141. The concentration of impurities in the third well tab 142 is higher than in the third well 14.

In an embodiment, the unit cell 10 further includes the fourth well 15 that is a low-voltage P type well formed on the substrate 11 between the second well 13 and the third well 14. The fourth well 15 can be formed on the substrate 11 through ion implantation. As described above, by forming the fourth well 15 which is a P type well, it is possible to prevent the surface of the substrate 11 which is P type from being changed to N type by the second and third wells 13 and 14 which are N type wells.

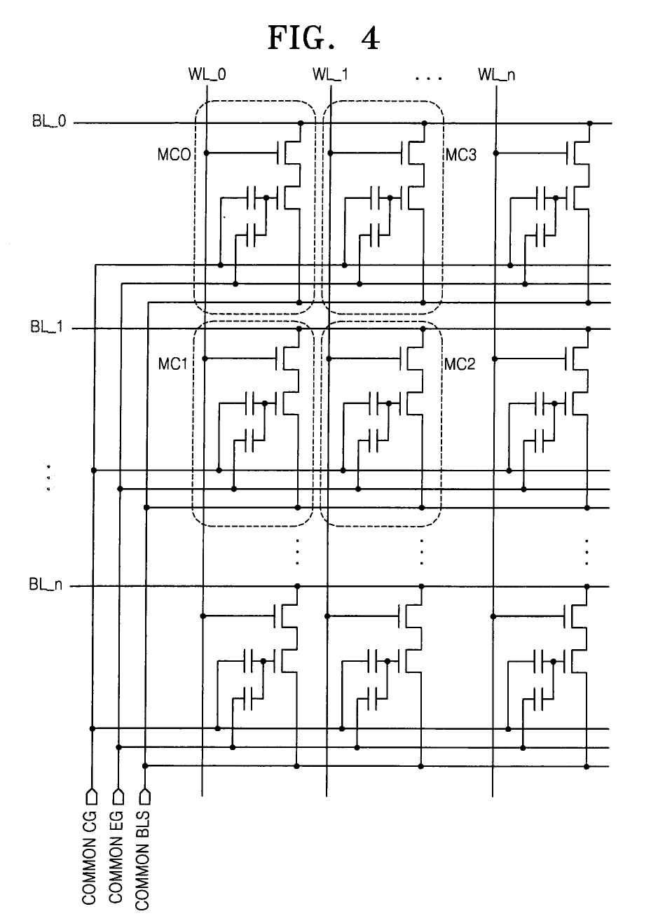

FIG. 4 is a circuit diagram of a nonvolatile memory cell array according to an embodiment. Referring to FIG. 4, the nonvolatile memory cell array includes multiple word lines WL_0, WL_1, . . . , WL-n; multiple bit lines BL 0, BL_1, . . . , BL_n that intersect word lines WL_0, WL_1, . . . , WL-n; multiple memory cells located at regions where the bit lines BL_0, BL_1, . . . , BL_n intersect the intersect word lines WL_0, WL_1, . . . , WL-n; a common control gate line commonly connected to the memory cells; a common erasing gate line commonly connected to the memory cells; and a common bit line selection line commonly connected to the memory cells. Hereinafter, for convenience of explanation, programming, reading data from, and erasing data from the nonvolatile memory cell array will be described with respect to first through fourth memory cells MC0, MC1, MC2, and MC3.

Table 1 illustrates voltages applied to the first through fourth memory cells MC0 through MC3 of the nonvolatile memory cell array. For example, a high voltage, e.g., 18 V, is necessary to operate conventional EEPROM. However, high voltage can be used but is not necessary to operate EEPROM according to an embodiment. Thus, a high-voltage process is not required accordingly. Here, the first memory cell MC0 is a memory cell to be programmed, and the second through fourth memory cells MC1 through MC3 are memory cells that are not programmed.

TABLE 1

| | | V_{EG} | V_{CG} | V_{WL} | V_{BL} | V_{BLS} | V_{PW} |
|---|---|---|---|---|---|---|---|
| Erasing | | 15-18 | 0 | 0 | 0 | 0 | 0 |
| Programming | MC0 | 10-12 | 10-12 | 5-8 | 0 | 5-8 | 0 |
| | MC1 | | | 5-8 | 5-8 | 5-8 | 0 |
| | MC2 | | | 0 | 5-8 | 5-8 | 0 |
| | MC3 | | | 0 | 0 | 5-8 | 0 |

| | | | | | | |
|---|---|---|---|---|---|---|
| Reading | 0 | 0 | 3-5 | Read | 0 | 0 |

Programming, reading data from, and erasing data from a memory cell will now be described with reference to FIGS. 3 and 4 and Table 1.

In order to erase data from the first through fourth memory cells MC0 through MC3, an erasing voltage VEG, e.g., 15 through 18 V, is applied to a common erasing gate line commonly connected to erasing gates of the first through fourth memory cells MC0 through MC3. Also, about 0 V, i.e., a ground voltage, is applied to a common control gate line commonly connected to control gates of the first through fourth memory cells MC0 through MC3. Also, all word line voltage VWL, bit line voltage VBL, and bit line selection voltage VBLS applied to the first through fourth memory cells MC0 through MC3, and voltage VPW applied to a P type substrate are about 0 V.

If the capacitance between a control gate and a floating gate is C1, the capacitance between an erasing gate and the floating gate is C2, and the capacitance between an access transistor and the floating gate is C3, then a capacitive coupling ratio can be controlled so that (C1+C3)/(C1+C2+C3) can be maintained to be equal to or greater than about 0.9 in order to apply a greater part of erasing voltage to the erasing gate and the floating gate. If a greater part of erasing voltage is applied to the erasing gate and the floating gate, FN (Fowler-Nordheim) tunneling occurs between the erasing gate and the floating gate. In this case, electrons stored in the floating gate move to the erasing gate, and thus, the floating gate assumes (+) charges.

For example, if the thickness of a gate oxide layer is about 140 Å, an erasing operation can be performed on a memory cell by applying erasing voltage from about 16 through about 18 V to an erasing gate for about 100 ms.

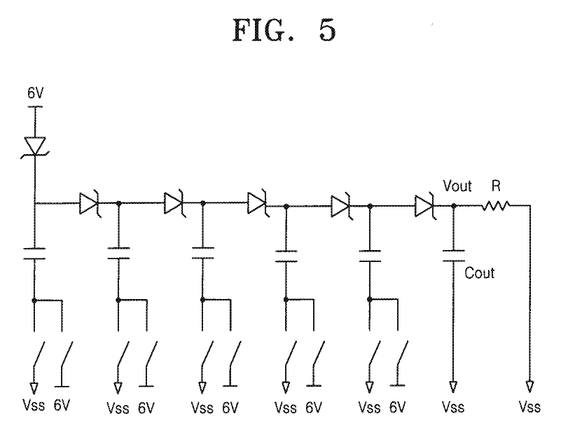

Such an erasing operation can, but need not be individually performed on memory cells. For example, the erasing operation can be uniformly performed by applying voltage to a common erasing gate line commonly connected to erasing gates of all the memory cells. Here, the common erasing gate line can provide a voltage either from one voltage booster circuit or a separate, external power supply, thereby preventing chip size from being increased (see FIG. 5 for an example of additional details).

In order to program the first through fourth memory cells MC0 through MC3, an erasing voltage VEG from about 10 to about 12 V is applied to the common erasing gate line commonly connected to the erasing gates of these memory cells, a program voltage VCG from about 10 to about 12 V is applied to a common control gate line commonly connected to control gates of these memory cells, and a bit line selection voltage VBLS from about 5 to about 8 V is applied to a common bit line selection line commonly connected to drains of an access transistors of these memory cells. As described above, the same erasing voltage VEG, the same program voltage VCG, and the same bit line selection voltage VBLS are applied to the first through fourth memory cells MC0 through MC3. However, in this case, voltage VPW applied to the P type substrate is about 0 V.

As described above, voltages respectively applied to the drain, control gate, and erasing gate of an access transistor are the same with respect to the first through fourth memory cells MC0 through MC3. Thus, programming is selectively performed on each of these memory cells based on a word line voltage VWL and a bit line voltage VBL applied to a selection transistor thereof.

In order to program the first memory cell MC0, a word line voltage and a bit line voltage applied to the first memory cell MC0 are respectively about 5 to about 8 V and about 0 V. Thus, the gate of a selection transistor included in the first memory cell MC0 is turned on by applying the word line voltage thereto, and the voltage of the drain of the selection transistor, i.e., the voltage of the source of the access transistor, becomes about 0 V. Accordingly, a voltage difference occurs between the source and drain of the access transistor, thereby forming a channel. Electrons in the channel become hot electrons, escape from an electric potential barrier of a gate oxide layer, and then are stored in a floating gate, thereby programming the first memory cell MC0.

In this case, it is possible to prevent a channel from formed between the source and drain regions of the access transistors included in the second through fourth memory cells MC1, MC2, and MC3 that are not programmed, by applying the same bit line selection voltage from about 5 through about 8 V to these memory cells.

As described above, according to an embodiment, a channel hot electron (CHE) method can be used in order to store electrons in a floating gate during programming of a memory cell. The CHE method enables programming to be performed by applying a lower voltage to a control gate than when using the FN tunneling method.

If the capacitance between a control gate and a floating gate is C1, the capacitance between an erasing gate and the floating gate is C2, and the capacitance between an access transistor and the floating gate is C3, then a capacitive coupling ratio can be controlled so that (C1+C2)/(C1+C2+C3) can be maintained to be equal to or greater than about 0.9 in order to apply a greater part of a program voltage to the access transistor and the floating gate. If a greater part of the program voltage applied to the control gate and an erasing gate applied to the erasing gate are applied to the access transistor and the floating gate, electrons are stored in the floating gate of the access transistor according to the CHE method.

In order to read data from the first through fourth memory cells MC0 through MC3, an erasing voltage VEG of about 0 V is applied to the common erasing gate line commonly connected to the erasing gates of these memory cells, a program voltage VCG of about 0 V is applied to the common control gate line commonly connected to the control gates of these memory cells, and a bit line selection voltage VBLS of about 0 V is applied to the common bit line selection line commonly applied to the drains of the access transistors of these memory cells. That is, the same erasing voltage VEG, the same program voltage VCG, and the same bit line selection voltage VBLS are applied with respect to the first through fourth memory cells MC0 through MC3. In this case, a voltage VPW applied to the P type substrate is also about 0 V.

As described above, the voltages respectively applied to the drain, control gate, and erasing gate of the access transistor are the same with respect to the first through fourth memory cells MC0 through MC3. Therefore, reading is selectively performed on each of the memory cells based on a word line voltage VWL and a bit line voltage VBL applied to a selection transistor thereof.

In order to read data from the first memory cell MC0, a word line voltage from 3 to 5 V is applied thereto, thereby turning on the selection transistor of the first memory cell MC0. If electrons are not stored in the floating gate, that is, if the first memory cell MC0 has an erased state, a channel is formed between the source/drain regions of the access transistor. If electrons are stored in the floating gate, that is, if the first memory cell MC0 has a programmed state, a channel is not formed between the source/drain regions of the access transistor. In theses cases, the voltage of the source of the selection transistor included in the first memory cell MC0 is read in order to perform reading on the first memory cell MC0.

FIG. 5 is a circuit diagram of a voltage booster circuit included in a nonvolatile memory device according to an embodiment. As illustrated in FIG. 4 and Table 1, high voltage is necessary to perform FN tunneling and the CHE method for erasing and programming a nonvolatile memory device according to an embodiment. Thus, a nonvolatile memory device includes a voltage booster circuit in order to generate a high voltage without performing a high-voltage process.

Referring to FIG. 5, the voltage booster circuit includes multiple diodes, multiple capacitors, multiple switches, and a resistor R. The voltage booster circuit is configured to boost an output voltage Vout by performing sequentially switching from the left direction. The output voltage Vout can be increased by increasing the value of the resistor R, for example, to over 10 MΩ so that a large part of electric charges can be accumulated in the capacitor Cout. Also, a schottky diode having a low turn-on voltage can be used in order to increase the efficiency of an increase in the output voltage Vout.

The output voltage Vout can be used as either a common program voltage VCG to be applied to a common control gate line commonly connected to a control gate of each of memory cells, or a common erasing voltage VEG to be applied to a common erasing gate line commonly connected to an erasing gate of each of the memory cells. In other words, a nonvolatile memory device according to an embodiment can include one voltage booster circuit for supplying a common program voltage to be commonly applied to multiple memory cells, and another voltage booster circuit for supplying a common erasing voltage to be commonly applied to the memory cells.

In another embodiment, a nonvolatile memory device is capable of supplying a common program voltage VCG or a common erasing voltage VEG by connecting an external power source to a common control gate line or a common erasing gate line without an additional voltage booster circuit.

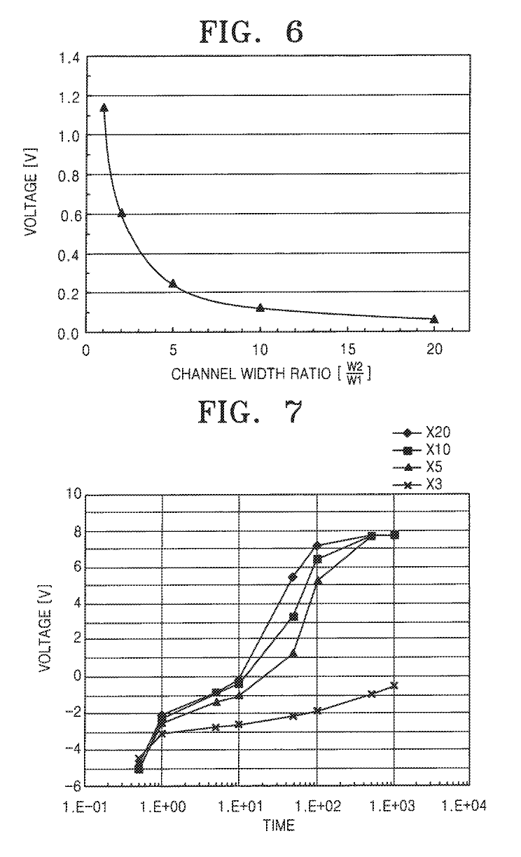

FIG. 6 is a graph illustrating a voltage at a point where two transistors, i.e., an access transistor and a selection transistor, which are included in a unit cell of a nonvolatile memory intersect each other, versus the ratio of the channel widths of the two channels, according to an embodiment. Referring to FIG. 6, the x-axis denotes the ratio of the channel width W2 of the selection transistor to the channel width W1 of the access transistor. The y-axis denotes a voltage at point where the access transistor and the selection transistor intersect each other, that is, the voltage of a source of the access transistor and the voltage of a drain of the selection transistor, when a bit line selection voltage applied to the access transistor is 6 V.

As described above, a nonvolatile memory device according to an embodiment programs memory cells according to the CHE method. Thus, the difference between the voltages of source and drain regions of an access transistor included in each of the memory cells must be set to be high enough for high-energy electrons to escape from a gate oxide layer and be stored in a floating gate, thereby performing programming.

However, in an embodiment, since a selection transistor and an access transistor are connected in series, the difference between the voltages of the source and drain regions of the access transistor is reduced by increasing the voltage of a source of the access transistor by using the selection transistor, and thus, the efficiency of programming is degraded. Accordingly, the source region of the access transistor must be minimized in order to maximize the difference between the voltages of the drain and source regions of the access transistor.

Referring to FIG. 6, when the channel width W1 of the access transistor is 1 and the channel width W2 of the selection transistor is equal to or greater than about 5, the voltage at the point where the access transistor and the selection transistor intersect each other is less than or equal to 0.2 V. Thus, according to an embodiment, the ratio of the channel width W2 of the selection transistor to the channel width W1 of the access transistor is set to be approximately 5:30.

FIG. 7 is a graph illustrating a variation in a threshold voltage when programming a unit cell of a nonvolatile memory versus the ratio of the channel widths of two transistors included in the unit cell, according to an embodiment. Referring to FIG. 7, the x-axis denotes programming time and the y-axis denotes a threshold voltage. In FIG. 7, ‘♦’ denotes a case where the ratio of the channel width W2 of a selection transistor to the channel width W1 of an access transistor is 1:20, ‘▪’ denotes a case where the ratio of the channel width W2 of a selection transistor to the channel width W1 of an access transistor is 1:10, ‘▴’ denotes a case where the ratio of the channel width W2 to the channel width W1 is 1:5, and ‘X’ denotes a case where the ratio of the channel width W2 to the channel width W1 is 1:3.

As illustrated in FIG. 7, if the ratio of the channel width W2 to the channel width W1 is 1:3, the threshold voltage is less than about 0 V even when a programming time increases. However, if the ratio of the channel width W2 to the channel width W1 is 1:20, the threshold voltage rapidly increase according to the programming time.

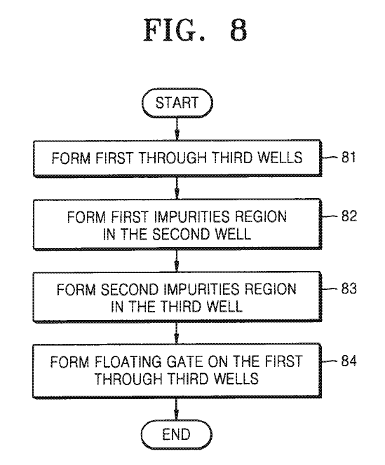

FIG. 8 is a flowchart illustrating a method of fabricating a nonvolatile memory device according to an embodiment. Referring to FIG. 8, in 81, first, second and third wells are formed on a substrate spaced apart from one another. In 82, a first impurities region is formed in the second well connected to a common control gate line. In 83, a second impurities region is formed in the third well connected to a common erasing gate line. In 84, a floating gate is formed on the first, second and third wells capacitively-coupled to a predetermined region of the first well, the first impurities region and the second impurities region.

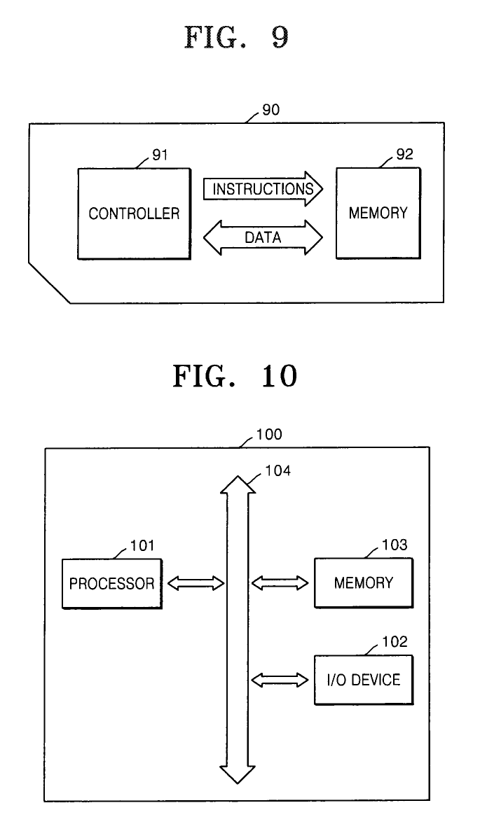

FIG. 9 is a block diagram schematically illustrating a card 90 according to an embodiment. Referring to FIG. 9, the card 90 can be constructed such that a controller 91 and a memory 92 can exchange electric signals with each other therein. For example, if the controller 91 gives a command to the memory 92, the memory 92 can transmit data. The memory 92 can include the nonvolatile memory device 10 illustrated in FIG. 1. The card 90 can be used as various memory devices, such as a memory stick card, a smart media card (SM), a secure digital (SD), a mini secure digital card; mini SD, a multi media card (MMC), or the like.

FIG. 10 is a block diagram schematically illustrating a system 100 according to an embodiment. Referring to FIG. 10, in the system 100, a processor 101, an input/output (I/O) device 102 and a memory 103 can establish a data communication with one another via a bus 104. The processor 101 can execute programs and control the system 100. The I/O device 102 can be used in order to supply data to or output data from the system 100. The system 100 can exchange data with an external device, e.g., a personal computer or a network, while being connected to the external device via the I/O device 102. The memory 103 can include the nonvolatile memory device 10 of FIG. 1. For example, the memory 103 can store code and data for operating and/or access by the processor 101. For example, the system 100 can be applied to the field of mobile phones, MP3 players, navigation, portable multimedia players (PMPs), solid state disks (SSDs), household appliances, or the like.

An embodiment includes a nonvolatile memory device that can be fabricated without performing a high-voltage process. Another embodiment includes a method of fabricating the same.

An embodiment includes a nonvolatile memory device including word lines, bit lines intersecting the word lines, memory cells located at regions where the word lines intersect the bit lines, a common control gate line commonly connected to the memory cells, a common erasing gate line commonly connected to the memory cells, and a common bit line selection line commonly connected to the memory cells.

Each of the memory cells can include a first transistor coupled to one of the bit lines, and a second transistor having a floating gate and connected to the first transistor in series. The floating gate can be capacitively-coupled to the common control gate line and the common erasing gate line. The first transistor can be connected to one of the word lines, and the second transistor can be connected to the common bit line selection line.

A memory cell that is to be programmed from among the memory cells can be selectively programmed based on voltages applied to one of the word lines and one of the bit lines.

The nonvolatile memory device can further include a first voltage booster circuit applying a voltage to the common control gate line, and a second voltage booster circuit applying a voltage to the common erasing gate line. A voltage can be applied to at least one of the common control gate line and the common erasing gate line, from an external power source.

The relationships among first capacitance C1 between the common control gate line and the floating gate, second capacitance C2 between the common erasing gate line and the floating gate, and third capacitance C3 between the second transistor and the floating gate, can be such that (C1+C2)/(C1+C2+C3)≧about 0.9 and (C1+C3)/(C1+C2+C3)≧about 0.9.

An embodiment includes a nonvolatile memory device including a substrate of a first conductive type; a first well of the first conductive type formed on the substrate; a second well of a second conductive type formed on the substrate spaced apart from the first well, and having a first impurities region connected to a common control gate line; a third well of the second conductive type formed on the substrate spaced apart from the first and second wells, and having a second impurities region connected to a common erasing gate line; and a floating gate formed in upper parts of the first through third wells, and capacitively-coupled to a predetermined region of the first well, the first impurities region, and the second impurities region.

The nonvolatile memory device can further include a first transistor formed in the first well and connected to one of multiple bit lines; and a second transistor formed in the first well, having the floating gate, and connected to the first transistor in series. The first transistor can be coupled to one of multiple word lines and the second transistor is coupled to a common bit line selection line.

A channel width of the first transistor can be greater than that of the second transistor. The channel width of the first transistor can be five to thirty times greater than that of the second transistor.

The nonvolatile memory device can further include a fourth well of the first conductive type formed between the second well and the third well on the substrate. The distance between the first well and the second well can be about 0.5 to 2 μm, and the distance between the second well and the third well can be about 2 to 4 μm.

The relationships among first capacitance C1 between the first impurities region and the floating gate, second capacitance C2 between the second impurities region and the floating gate, and third capacitance C3 between the second transistor and the floating gate, can be such that (C1+C2)/(C1+C2+C3)≧about 0.9 and (C1+C3)/(C1+C2+C3)≧about 0.9.

The nonvolatile memory device can further include at least one of a first well tab of the first conductive type formed in the first well, where the concentration of impurities of the first well tab is higher than that of the first well; a second well tab of the second conductive type formed in the second well, where the concentration of impurities of the second well tab is higher than that of the second well; and a third well tab of the second conductive type formed in the third well, where the concentration of impurities of the third well tab is higher than that of the third well.

The nonvolatile memory device can further include at least one of a first voltage booster circuit applying a voltage to the common control gate line, and a second voltage booster circuit applying a voltage to the common erasing gate line.

A voltage can be applied to at least one of the common control gate line and the common erasing gate line, from an external power supply.

Another embodiment includes a method of fabricating a nonvolatile memory device, the method including forming first, second and third wells on a substrate spaced apart from one another; forming a first impurities region in the second well coupled to a common control gate line; forming a second impurities region in the third well coupled to a common erasing gate line; and forming a floating gate in upper parts of the first, second and third wells capacitance-coupled to a predetermined region of the first well, the first impurities region and the second impurities region.

An embodiment includes computer readable code embodied in a computer readable medium. Here, the computer readable medium can be any recording apparatus capable of storing data that is read by a computer system, e.g., a read-only memory (ROM), a random access memory (RAM), a compact disc (CD)-ROM, a magnetic tape, a floppy disk, an optical data storage device, and so on. Also, the computer readable medium can be a carrier wave that transmits data via the Internet, for example. The computer readable medium can be distributed among computer systems that are interconnected through a network, and an embodiment can be stored and implemented as computer readable code in the distributed system. Here, the code (or a program) in a computer readable medium can include a series of instructions directly or indirectly used in a device, e.g., a computer, which has the capability of processing information in order to obtain a specific result. Thus, the term, ‘computer’ is used to indicate various devices that can include a memory, an I/O device, and an arithmetic device, or the like, and are capable of processing information in order to perform a specific operation according to a program.

The foregoing is illustrative of the embodiments and is not to be construed as limiting thereof. Although embodiments have been described, those skilled in the art will readily appreciate that many modifications are possible without materially departing from the novel teachings and advantages of the embodiments. Accordingly, all such modifications are intended to be included within the scope of the following claims. Therefore, it is to be understood that the foregoing is illustrative of embodiments and is not to be construed as limited to the specific embodiments disclosed, and that modifications to the disclosed embodiments, as well as other embodiments, are intended to be included within the scope of the following claims.

1. A nonvolatile memory device comprising:
a plurality of word lines;
a plurality of bit lines intersecting the word lines;
a plurality of memory cells corresponding to intersections of the word lines and the bit lines;
a common control gate line commonly connected to the memory cells; and
a common erasing gate line commonly connected to the memory cells.

2. The nonvolatile memory device of claim 1, wherein each of the memory cells comprises:
a first transistor coupled to one of the bit lines; and
a second transistor having a floating gate and connected in series with the first transistor.

3. The nonvolatile memory device of claim 2, wherein for each of the memory cells, the floating gate is capacitively-coupled to the common control gate line and the common erasing gate line.

4. The nonvolatile memory device of claim 2, wherein for each of the memory cells, the first transistor is connected to one of the word lines, and the second transistor is connected to a common bit line selection line.

5. The nonvolatile memory device of claim 2, each memory cell further comprising:
a first capacitor connected between the floating gate and the common control gate line; and
a second capacitor connected between the floating gate and the common erasing gate line.

6. The nonvolatile memory device of claim 1, further comprising at least one of:
a first voltage booster circuit configured to apply a voltage to the common control gate line; and
a second voltage booster circuit configured to apply a voltage to the common erasing gate line.

7. The nonvolatile memory device of claim 1, further comprising a terminal connected to at least one of the common control gate line and the common erasing gate line such that a voltage from an external power source can be applied to the at least one of the common control gate line and the common erasing gate line.

8. The nonvolatile memory device of claim 3, wherein the relationships among first capacitance C1 between the common control gate line and the floating gate, second capacitance C2 between the common erasing gate line and the floating gate, and third capacitance C3 between the second transistor and the floating gate are (C1+C2)/(C1+C2+C3)≧about 0.9 and (C1+C3)/(C1+C2+C3)≧about 0.9.

9. A nonvolatile memory device comprising:
a substrate of a first conductive type;
a first well of the first conductive type formed on the substrate;
a second well of a second conductive type formed on the substrate to be spaced apart from the first well, and having a first impurities region connected to a common control gate line;
a third well of the second conductive type formed on the substrate to be spaced apart from the first and second wells, and having a second impurities region connected to a common erasing gate line; and
a floating gate formed on the first through third wells, and capacitively-coupled to a region of the first well, the first impurities region, and the second impurities region.

10. The nonvolatile memory device of claim 9, further comprising:
a first transistor formed in the first well and connected to one of a plurality of bit lines; and
a second transistor formed in the first well, having the floating gate, and connected to the first transistor in series.

11. The nonvolatile memory device of claim 10, wherein the first transistor is coupled to one of a plurality of word lines and the second transistor is coupled to a common bit line selection line.

12. The nonvolatile memory device of claim 10, wherein a channel width of the first transistor is greater than a channel width of the second transistor.

13. The nonvolatile memory device of claim 12, wherein the channel width of the first transistor is greater than about five times the channel width of the second transistor.

14. The nonvolatile memory device of claim 9, further comprising a fourth well of the first conductive type formed between the second well and the third well on the substrate.

15. The nonvolatile memory device of claim 9, wherein the distance between the first well and the second well is about 0.5 to about 2 μm, and the distance between the second well and the third well is about 2 to about 4 μm.

16. The nonvolatile memory device of claim 9, wherein the relationships among a first capacitance C1 between the first impurities region and the floating gate, a second capacitance C2 between the second impurities region and the floating gate, and a third capacitance C3 between the second transistor and the floating gate are (C1+C2)/(C1+C2+C3)≧about 0.9 and (C1+C3)/(C1+C2+C3)≧about 0.9.

17. The nonvolatile memory device of claim 9, further comprising at least one of:
a first well tab of the first conductive type formed in the first well, where the concentration of impurities of the first well tab is higher than that of the first well;
a second well tab of the second conductive type formed in the second well, where the concentration of impurities of the second well tab is higher than that of the second well; and
a third well tab of the second conductive type formed in the third well, where the concentration of impurities of the third well tab is higher than that of the third well.

18. The nonvolatile memory device of claim 9, further comprising at least one of:
a first voltage booster circuit configured to apply a voltage to the common control gate line; and
a second voltage booster circuit configured to apply a voltage to the common erasing gate line.

19. The nonvolatile memory device of claim 9, wherein a voltage is applied to at least one of the common control gate line and the common erasing gate line, from an external power supply.

20. (canceled)
